(19) United States
(12) Patent Application Publication
(10) Pub. No.: US 2021/0317271 A1
(43) Pub. Date: Oct. 14, 2021

(54) COMPOSITION PRECURSOR, COMPOSITION, METHOD FOR PRODUCING A COMPOSITION PRECURSOR, METHOD FOR PRODUCING A COMPOSITION, USE OF A COMPOSITION, AND COMPONENT

(71) Applicant: Universität des Saarlandes, Saarbrücken (DE)

(72) Inventors: Guido Kickelbick, St. Ingbert (DE); Nils Steinbrück, Wenzenbach (DE); Svenja Pohl, Saarbrücken (DE)

(21) Appl. No.: 17/269,196

(22) PCT Filed: Aug. 20, 2019
(86) PCT No.: PCT/EP2019/072254

§ 371 Date: Feb. 17, 2021

(30) Foreign Application Priority Data
Aug. 23, 2018 (EP) 18190475.6

(51) Int. Cl. C08G 77/06; C08L 83/04; H01L 33/56

(52) U.S. Cl. CPC C08G 77/06; H01L 33/56; C08L 83/04

(57) ABSTRACT

A composition precursor including a three-dimensional network consisting of partially cross-linked monomer units and an alkoxy-terminated oligo- or polysiloxane, wherein the monomer units comprise at least one trialkoxysilane and at least one dialkoxysilane. Also disclosed are a composition, a method for producing a composition precursor and a composition, use of a composition and a component.

The application relates to a composition precursor, to a composition, to a process for producing a composition precursor, to a process for producing a composition, to use of the composition and to a component.

Polysiloxanes are used in many sectors. Ever higher demands are being made on these materials, and so there is a need to improve commercially available systems. One possible use of polysiloxanes is, for example, the encapsulation of optoelectronic components. The working conditions for light-emitting diodes (LEDs) require, for example, high photophysical and thermal stability, high transparency, high refractive index, and good processibility of the cured and uncured encapsulation materials, in order to assure a high efficiency and long lifetime of the component.

For example, polysiloxane-based encapsulation materials that are based on two-component elastomer systems and are thermally curable by means of a platinum catalyst are employed. For environmental and economic reasons, however, the use of non-recyclable precious metals such as platinum should be avoided. However, epoxy-based polysiloxanes known to date that can be cured without platinum are heat- or light-sensitive, such that, for example, discoloration occurs owing to the presence of the epoxy groups. Another requirement is often high flexibility of the materials, which has not been achievable to date.

It is an object of at least one embodiment of the invention to provide a composition precursor having improved properties. It is a further object of the invention to provide a composition having improved properties. Further objects are the provision of a process for producing a composition precursor having improved properties, and a process for producing a composition having improved properties. It is a further object of the invention to provide for use of the composition having improved properties. Finally, it is a further object of the invention to provide a component that comprises the composition and has improved properties.

These objects are achieved by the subject matter of the independent claims. Advantageous configurations and developments of the invention are subject matter of dependent claims and the description.

A composition precursor having a three-dimensional network of partly mutually crosslinked monomer units and an alkoxy-terminated oligo- or polysiloxane is specified.

A composition precursor here and hereinafter is understood to mean a material convertible to a composition by the action of outside influences. The outside influences initiate chemical reactions in the composition precursor that alter the chemical structure of the composition precursor in such a way that it is converted to the composition. Properties that result from the material of the composition can be achieved by controlling the properties of the composition precursor.

The composition precursor may be a polymeric material having the three-dimensional network. It should be noted here that not all constituents of the composition precursor must be crosslinked, but may also be present individually. The composition precursor thus comprises monomer units, alkoxy-terminated oligo- or polysiloxane, and monomer units that are joined to one another by chemical bonds, and also monomer units and alkoxy-terminated oligo- or polysiloxane that are joined to one another by chemical bonds.

“Monomer units” here and hereinafter are therefore understood to mean both unreacted monomers and units of a polymer chain that originate from these monomers.

In one embodiment, the monomer units comprise at least one trialkoxysilane and at least one dialkoxysilane.

What is meant in this connection by the monomer units comprising at least one trialkoxysilane (also referred to hereinafter as TAS) and at least one dialkoxysilane (also referred to hereinafter as DAS) is that it is also possible for at least two different trialkoxysilanes or at least two different dialkoxysilanes to be present as monomer units in the composition precursor.

The composition precursor formed by partial crosslinking from at least one TAS, at least one DAS and an alkoxy-terminated oligo- or polysiloxane may have a gel-like consistency and hence, for example, be in fluid or viscous form at room temperature.

The viscosity and refractive index of the composition precursor can be adjusted via the selection of the starting materials, i.e. of the monomer units and the alkoxy-terminated oligo- or polysiloxane, and the ratio of the proportions of the respective starting materials. For example, these properties are in direct correlation with the ratio of TAS to DAS used and the proportion of particular groups, especially bulky groups such as aryl groups, in the monomer units. In addition, the alkoxy-terminated oligo- or polysiloxane leads to an opened-up three-dimensional network composed of the partly mutually crosslinked monomer units, which in turn has an influence on the viscosity.

The adjustment of the viscosity and refractive index of the composition precursor can also influence the hardness and refractive index of a composition produced from the composition precursor, and hence adjust them according to the desired application.

In one embodiment, a composition precursor having a three-dimensional network of partly mutually crosslinked monomer units and an alkoxy-terminated oligo- or polysiloxane is specified, wherein the monomer units include at least one trialkoxysilane and at least one dialkoxysilane.

In a further embodiment, the composition precursor has the general structural formula

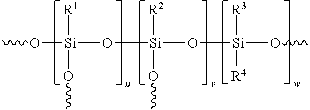

In this formula, R², R², R³ and R⁴ may independently be selected from aryl, alkyl, alkenyl, allyl, substituted aryl, substituted alkenyl, substituted alkyl and vinyl, preferably from phenyl and methyl, where u+v+w is the number of silicon atoms used, and u, v and w are independently selected from the range of 1 to 20 000.

In this structural formula, it should be noted that the groups indicated by u, v and w are distributed randomly in the at least partly crosslinked network. It is thus also possible for other sequences of the groups to occur in the network.

For example, it is thus possible to use, in the composition precursor, partly mutually crosslinked or else uncrosslinked phenyltrimethoxysilane PhSi(OMe)₃ and methyltrimethoxysilane MeSi(OMe)₃ as trialkoxysilanes, dimethyldimethoxysilane Me₂Si(OMe)₂ as dialkoxysilane, and methoxy-terminated polydimethylsiloxane, PDMSi₁₁ (OMe)₂, as alkoxy-terminated oligo- or polysiloxane. Their general structures are shown below:

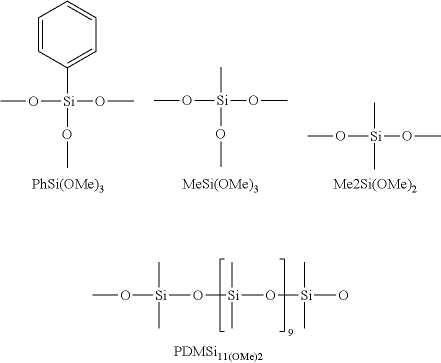

According to this example, the general structural formula of such a network formed therefrom may have the following appearance:

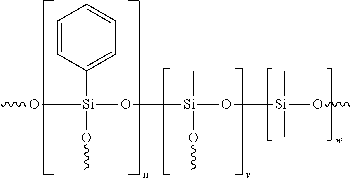

The higher the proportion of DAS in relation to TAS and alkyl-terminated oligo- or polysiloxane, the more open and less crosslinked the structure of the composition precursor and hence also of the resultant composition, which significantly reduces the viscosity of the composition precursor or the hardness of the composition. At the same time, the refractive index can rise on account of the greater ratio of, for example, phenyl to methyl groups.

In a further embodiment, the proportion of alkoxy-terminated oligo- or polysiloxane in the composition precursor is selected from a range from >0% to 10% of the sum total of the molar amounts of trialkoxysilane and dialkoxysilane. Such a proportion is sufficient to open up the three-dimensional network and hence lower the viscosity of the composition precursor.

In a further embodiment, the composition precursor has a viscosity at 23° C. within a range from 1 000 000 mPas to 100 mPas, and/or a viscosity at 110° C. within a range from 10 000 mPas to 50 mPas. These viscosities enable good processibility of the composition precursor. Moreover, they result in a hardness of the composition produced from the composition precursor that achieves a desired flexibility and elasticity of the composition.

In a further embodiment, the composition precursor is thermally or photochemically curable. This means that the composition precursor can be fully cured by thermal or photochemical effects, such that all or at least largely all monomer units and alkoxy-terminated oligo- or polysiloxanes are crosslinked with one another to form a three-dimensional network. This curing operation can also be referred to here and hereinafter as consolidation.

Also specified is a composition comprising a thermally or photochemically cured composition precursor according to any of the abovementioned embodiments. All features disclosed in association with the composition precursor are thus also applicable to the composition, and vice versa.

By virtue of the composition containing a thermally or photochemically cured composition precursor, it is not in gel form like the composition precursor, but firm. On account of the properties of the composition precursor, however, the composition has sufficiently high elasticity that it has good usability in many applications, for example as encapsulation in optoelectronic components.

In a further embodiment, the composition has a Shore A hardness of 40 to <99.

According to the nature of the composition precursor, the composition may also have a high refractive index. This may be greater than or equal to the refractive index of the composition precursor.

In a further embodiment, the composition is free of any precious metal catalyst. More particularly, the composition is free of any platinum catalyst. The composition is thus producible in a cost- and process-optimized manner. If the composition is based on a composition precursor comprising phenyltrimethoxysilane PhSi(OMe)₃ and methyltrimethoxysilane MeSi(OMe)₃ as trialkoxysilanes, dimethyldimethoxysilane Me₂Si(OMe)₂ as dialkoxysilane and methoxy-terminated polydimethylsiloxane, PDMSi₁₁ (OMe)₂ as alkoxy-terminated oligo- or polysiloxane, the cured or consolidated structure, in an illustrative detail, may have the following schematic formula:

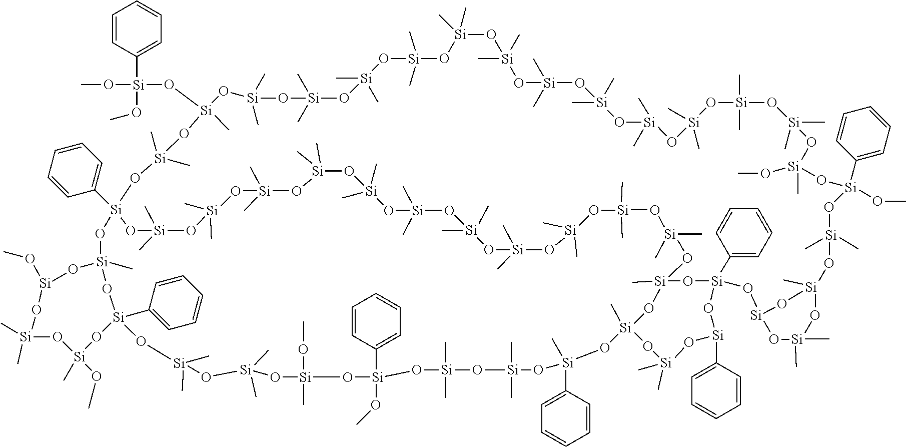

In this formula, the TAS and DAS groups and the PDMS groups that open up the network are apparent.

Also specified is a process for producing a composition precursor. The process has the steps of

A) condensing at least one trialkoxysilane and at least one dialkoxysilane,

B) condensing the at least one trialkoxysilane and the at least one dialkoxysilane with an alkoxy-terminated oligo- or polysiloxane,

C) purifying the condensed trialkoxysilane, dialkoxysilane and alkoxy-terminated oligo- or polysiloxane.

In one embodiment, process step B) can be performed after process step A) or simultaneously with process step A)

Condensation is understood here and hereinafter to mean a reaction of the monomer units with one another or with the alkoxy-terminated oligo- or polysiloxane in which the monomer units and the alkoxy-terminated oligo- or polysiloxane become chemically bonded to one another. This forms a three-dimensional network. However, it should be noted that, in this process, not all monomer units and not every alkoxy-terminated oligo- or polysiloxane react with one another, such that only partial crosslinking occurs.

In the process, it is also possible for at least two different trialkoxysilanes and/or at least two different dialkoxysilanes to condense.

Regardless of whether process steps A) and B) are performed simultaneously or successively, it is possible by this process to obtain a random distribution of the constituents used in the composition precursor. In addition, the alkoxy-terminated oligo- or polysiloxane ensures that an opened-up network of mutually condensed monomer units is formed.

By this process, it is possible to produce a composition precursor according to the abovementioned embodiments. All features disclosed in association with the composition precursor are thus also applicable to the process, and vice versa.

In one embodiment, process steps A) and B) are performed at a temperature selected from the range of 20° C. to 60° C., and/or process step C) is performed at a temperature selected from the range of 70° C. to 150° C. At these temperatures, the formation of a three-dimensional network of at least partly mutually crosslinked trialkoxysilanes, dialkoxysilanes and alkoxy-terminated oligo- or polysiloxane is promoted.

In a further embodiment, process step A) is performed with addition of an acid or base. Acids used may, for example, be HCl, H₂SO₄, vinegar or formic acid. Illustrative bases are NaOH, KOH, NH₄OH or NH₃. In general, the acids or bases used are water-soluble. If an acid is added, protonation of the alkoxy groups and hence an increase in the electrophilicity at the silicon atom can be achieved. As a result, water and alkoxysilane and silanol groups can attack and replace methanol as leaving group. Bases can directly attack the nucleophilic silicon atom and form a charged transition state. The alkoxysilane group can thus be replaced in an SN2-like reaction. If an acid is added in process step A), the probability of formation of catenated structures can increase; if a base is added, the probability of formation of branched structures can increase.

In a further embodiment, prior to process step C), the condensed trialkoxysilane, dialkoxysilane and alkoxy-terminated oligo- or polysiloxane is stirred at room temperature. This means that a gelation is conducted prior to the purification step C), which increases the viscosity of the material.

In the purification step C), water formed during the gelation, and also HCl and methanol formed by the condensation, can be removed.

Also specified is a process for producing a composition in which a composition precursor produced according to the above details is thermally or photochemically cured. The action of heat or light can thus produce a firm composition from the composition precursor in gel form. All the features mentioned in association with the process for producing a composition precursor are thus also applicable to the process for producing the composition, and vice versa.

In a further embodiment, the thermal curing is performed at a temperature from the range of 150° C. to 250° C. and/or for a duration from the range of 8 h to 72 h.

When a photochemically activatable group is present, photochemical curing can be performed in a monomer, for example a propyl methacrylate group. After addition of a photo initiator, these groups can react with one another. In addition, it is also possible to use photoacids that release protons on illumination for activation of the curing.

In a further embodiment, it is possible to add a base or acid as catalyst to the composition precursor. In the case of addition of a base, for example, it is possible to considerably reduce curing time and curing temperature. The base used may, for example, be KOH or DABCO (triethylenediamine). The proportion of base may, for example, be <10 mmol/g.

The composition obtained by the process is free of cracks, flexible and elastic according to the composition precursor used, and has a high refractive index.

Also specified is the use of a composition according to the above embodiments. The use of the composition comprises use as encapsulation material for optoelectronic components, as matrix material for conversion layers, as lens material, as anticorrosion material, as component in composite materials, in lithography processes and in printing technology.

For example, the composition can be used as positive in an embossing lithography process, into which a die is introduced. In addition, the composition can be employed, for example, photolithography processes, especially in a photolithographic 3D printing operation. In addition, the composition can serve as matrix for dyes, for example in solar cells or luminescence solar concentrators, for which the materials are deposited in thin films by means of inkjet methods.

Owing to the option of adjusting the refractive index and elasticity and flexibility in the composition, it is advantageously possible to use the composition in many sectors.

Also specified is a component including at least one assembly comprising a composition according to the details above. The component may, in one embodiment, be an optoelectronic component and comprise an encapsulation including the composition and/or a conversion layer including the composition.

The optoelectronic component may, for example, be a light-emitting diode (LED), and this may have a semiconductor layer sequence suitable for emission of primary radiation. An LED may have a conversion layer which is disposed in the beam path of the primary radiation and is set up to convert the primary radiation to secondary radiation. The encapsulation may be disposed in the component such that it surrounds the semiconductor layer sequence.

The composition is of good suitability as encapsulation material for LEDs on account of its high refractive index, its high transparency and its stability toward radiation and heat.

In a further embodiment, the composition in the conversion layer may be a matrix material for a dye that converts the primary radiation to secondary radiation. The composition is advantageously usable here since it is stable to light and heat and hence can contribute to a long lifetime and reliability of the component.

In addition, the conversion layer may take the form of a plaque or of an encapsulation. In the case of an encapsulation, the conversion layer may completely surround the semiconductor layer sequence.

If the composition is to be used in a component, the composition precursor, optionally incorporating further substances, for example dyes, is first applied at the desired site. This is performable in a particularly efficient manner on account of the low viscosity of the composition precursor and hence the good processibility thereof. As soon as it has been applied, the curing or consolidation can be performed, which forms the hard but still elastic composition, the hardness of the composition being adjustable by suitable adjustment of the composition precursor.

Further advantages, advantageous embodiments and developments will be apparent from the working examples described hereinafter in conjunction with the figures.

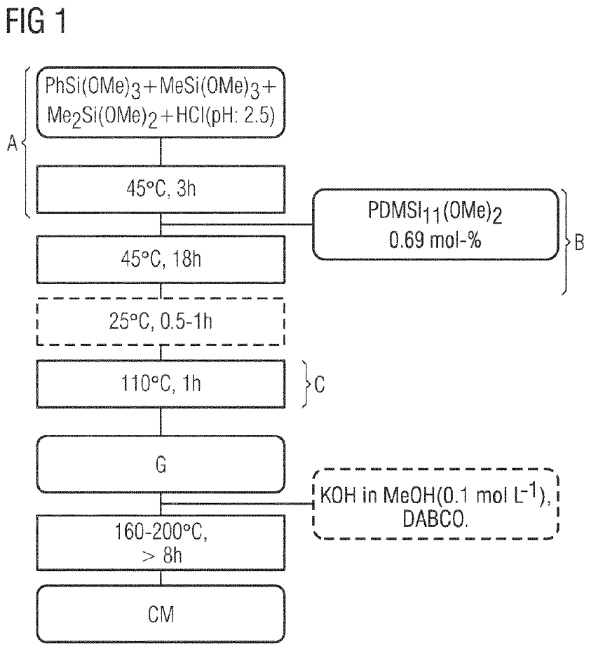

FIG. 1 shows a schematic view of the process for producing a composition precursor and a composition.

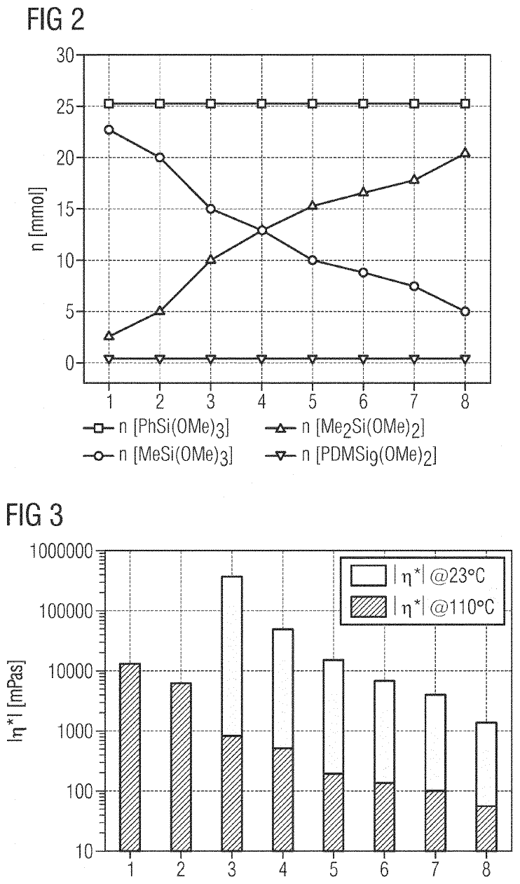

FIG. 2 shows a graphical representation of portions of starting materials used for production of the composition precursor in various working examples.

FIG. 3 shows the absolute viscosity of working examples of the composition precursor using a block diagram.

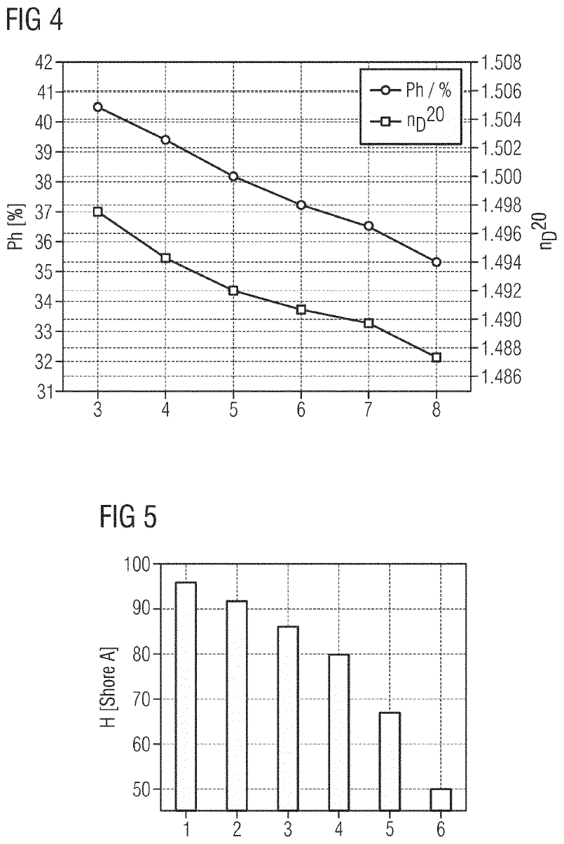

FIG. 4 shows a representation of the refractive indices and the content of phenyl groups of working examples of the composition precursor.

FIG. 5 shows a representation of the Shore A hardness of working examples of the composition using a block diagram.

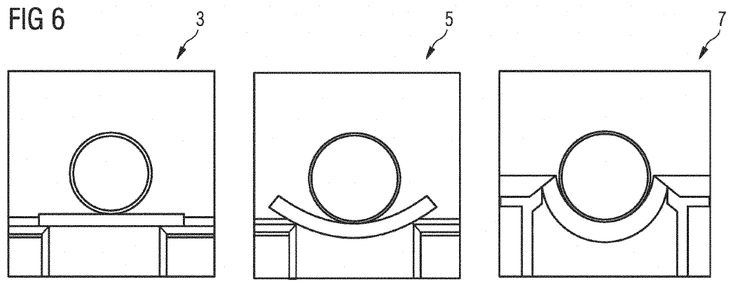

FIG. 6 shows images of plaques according to working examples of the composition.

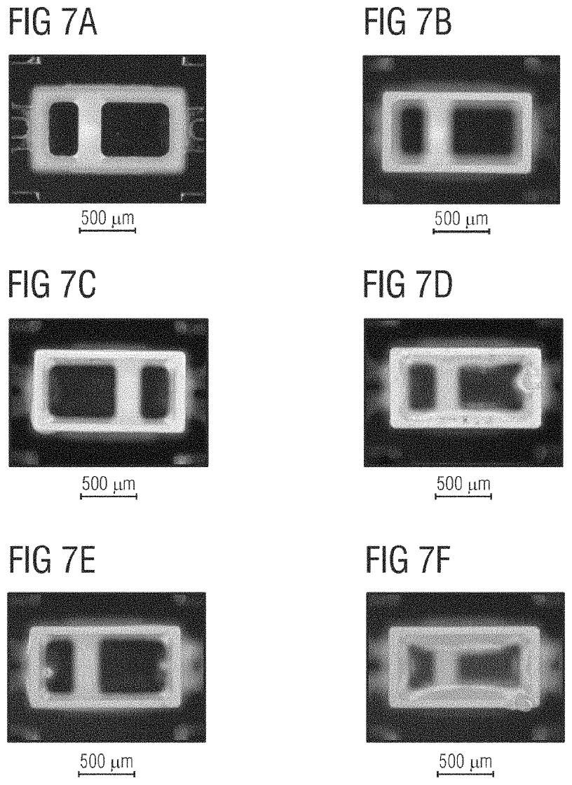

FIGS. 7a to 7f show leadframes without and with composition precursors and compositions according to working examples.

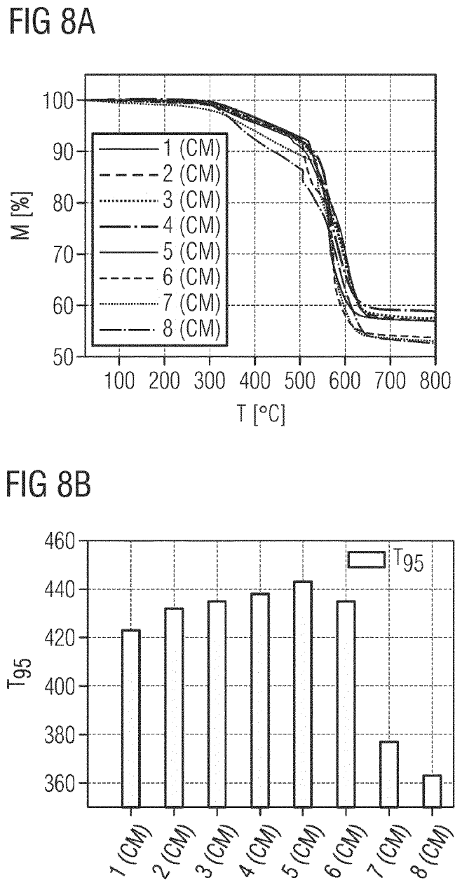

FIG. 8 shows the thermogravimetric loss of mass (a) and T₉₅ values (b) of working examples of the composition.

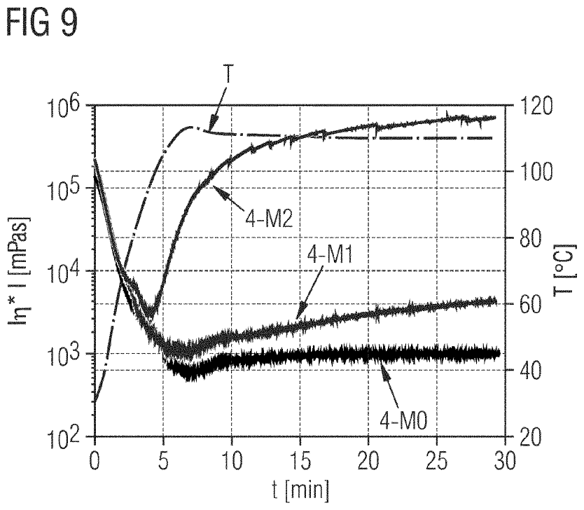

FIG. 9 shows the absolute viscosity as a function of time for working examples of the composition precursor.

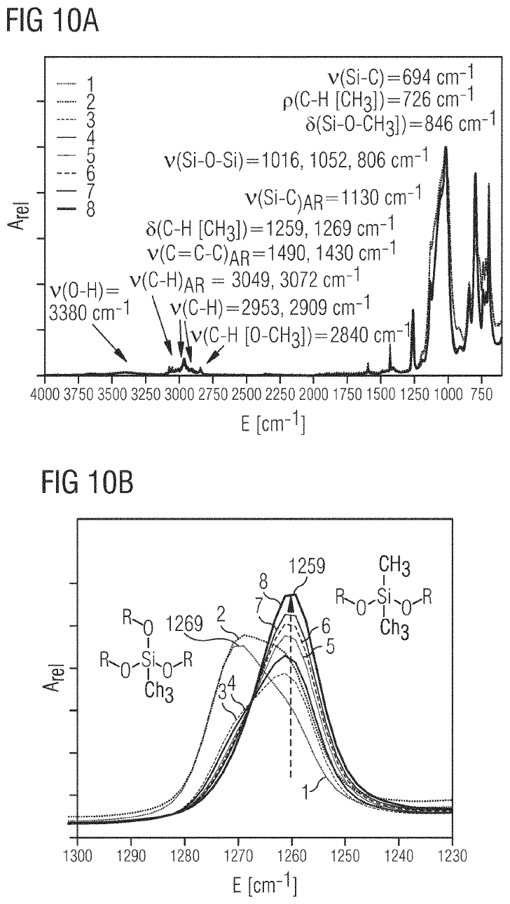

FIG. 10 shows FTIR spectra of working examples of the composition precursor.

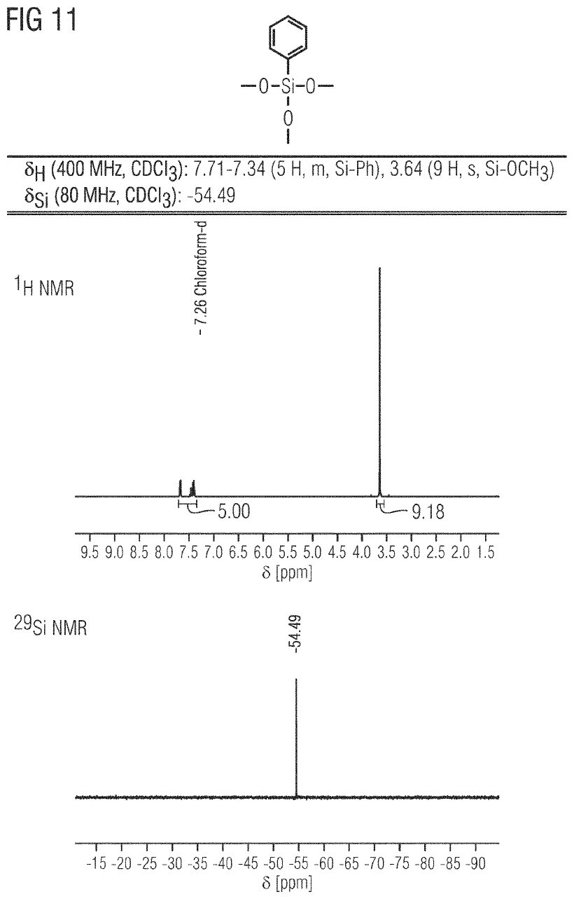

FIGS. 11 to 14 show ¹H and ²⁹Si NMR spectra of starting materials for production of a composition precursor.

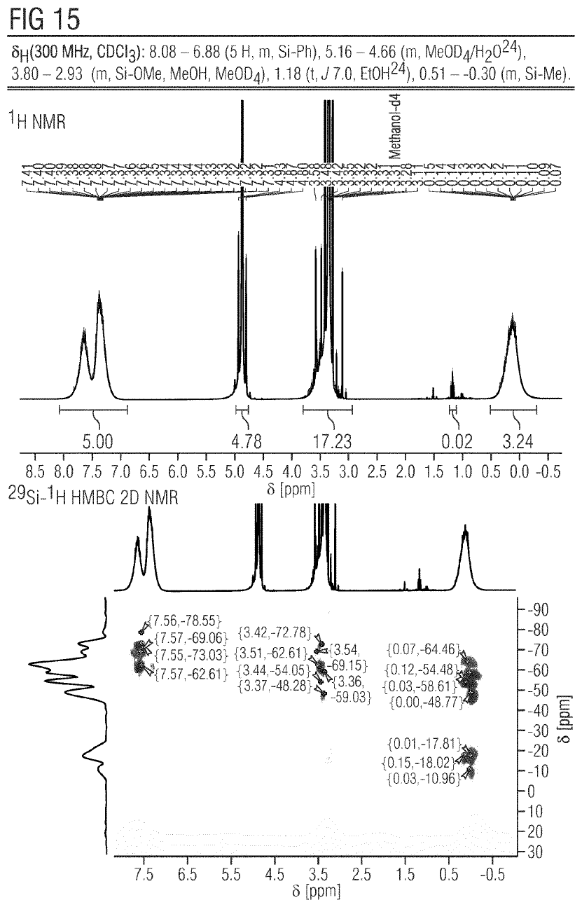

FIGS. 15 to 20, 25 and 26 show ¹H NMR spectra and ²⁹Si—¹H HMBC 2D NMR spectra of working examples of the composition precursor during and after production thereof.

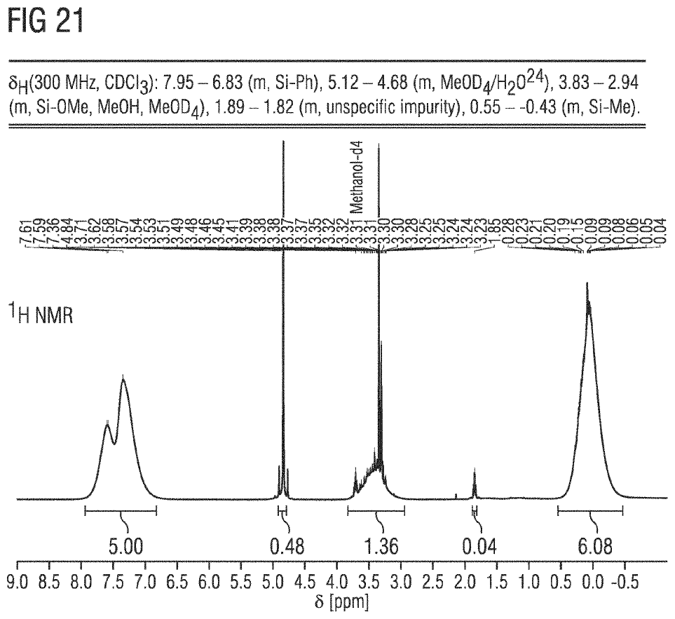

FIGS. 21 to 24 show ¹H NMR spectra of working examples of composition precursors.

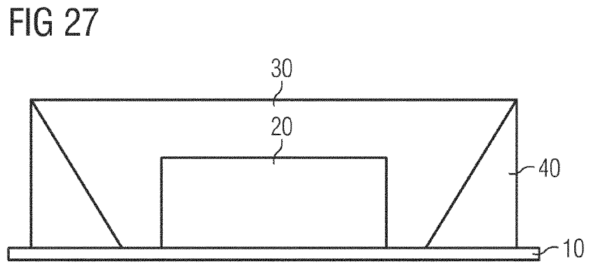

FIG. 27 shows the schematic side view of a component.

In the working examples and figures, elements that are identical, of the same type or have the same effect may each be given the same reference numerals. The elements shown and their size ratios relative to one another should not be regarded as being true to scale. Instead, individual elements, for example layers, assemblies, components and regions, for better illustration and/or for better understanding, may be shown in a disproportionately large size.

For production of working examples of composition precursors and compositions, for example, the following starting materials and auxiliaries may be used: dimethyldimethoxy-silane (97%, ABCR GmbH), methyltrimethoxysilane (97%, ABCR GmbH), phenyltrimethoxysilane (97%, ABCR GmbH), methoxy-terminated polydimethylsiloxane (5 to 12 cSt., ABCR GmbH), 1,4-diazabicyclo[2.2.2]octane (98% Alfa Aesar, Germany), hydrochloric acid (Bernd Kraft GmbH) and potassium hydroxide (85%, GrUssing GmbH Analytica). The hydrochloric acid is dissolved in demineralized water (pH=2.3). Potassium hydroxide is dissolved in methanol (0.11 mol/1).

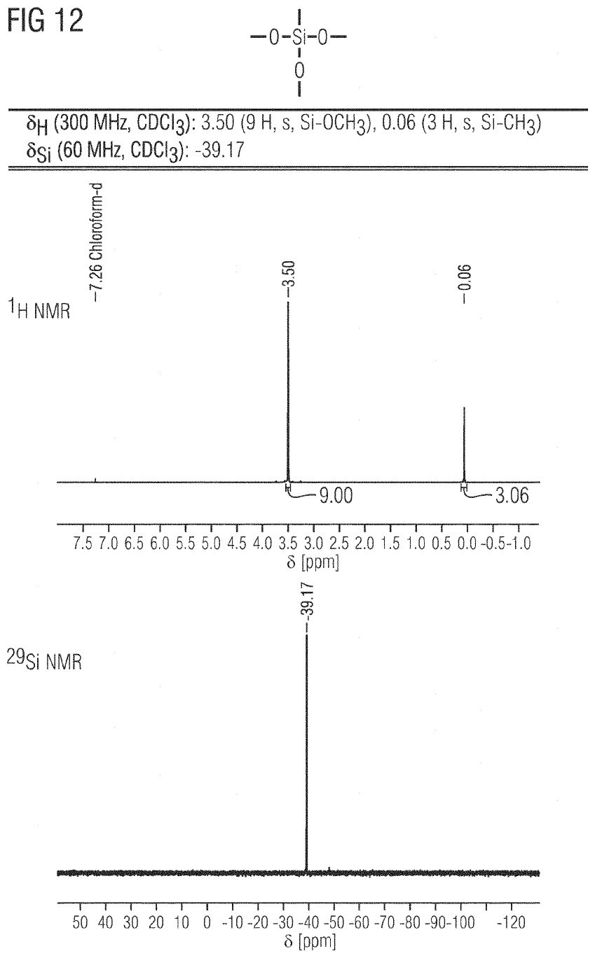

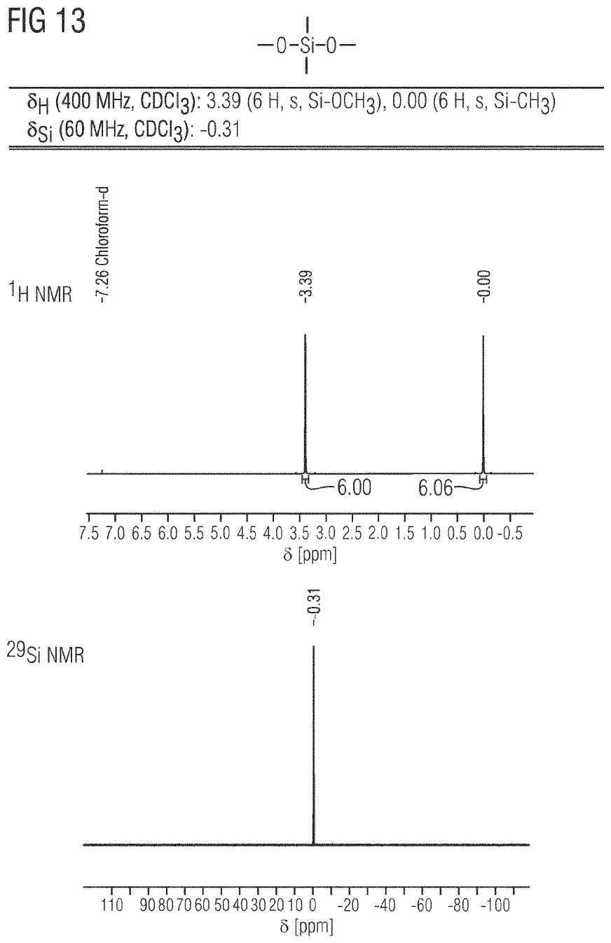

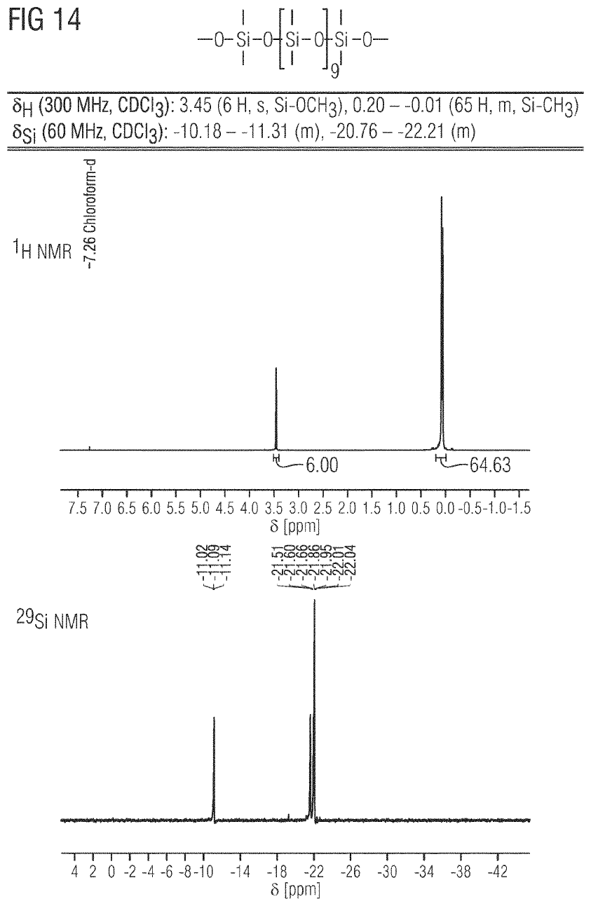

The purity of the starting materials and the average chain length of the methoxy-terminated polydimethylsiloxane are ascertained by means of ¹H and ²⁹Si NMR spectroscopy (see FIGS. 11 to 14: FIG. 11 shows the spectra of phenyltrimethoxysilane, FIG. 12 shows the spectra of methyltrimethoxysilane, FIG. 13 shows the spectra of dimethyldimethoxysilane, and FIG. 14 shows the spectra of methoxy-terminated polydimethylsiloxane). The NMR spectra were recorded with an Avance III 300 MHz spectrometer and an Avance III HD 400 MHz spectrometer (Bruker Corp., USA), at 300.13/400.13 MHz for ¹H NMR spectra and 59.63/79.49 MHz for ²⁹Si NMR spectra. The samples to be analyzed were dissolved in methanol-d4 or chloroform-d.

FIG. 1 shows a schematic view of the process for producing a composition precursor and a composition using a working example. First of all, hydrochloric acid having a pH of 2.5 is added to PhSi(OMe)₃ as TAS, MeSi(OMe)₃ as TAS and Me₂Si(OMe)₂ as DAS. The hydrochloric acid is added in a proportion of 1.5 times the molar amount of the alkoxysilanes. This mixture is stirred in a closed vessel at 45° C. and at 320 rpm for 3 hours. This is identified as process step A) in FIG. 1. In process step B), methoxy-terminated polydimethylsiloxane PDMSi₁₁ (Me0)₂ is added in a proportion of 0.7% of the molar amount of the alkoxysilanes, and stirring is continued at 45° C. and at 320 rpm for 18 hours. The addition of the PDMSi₁₁ (Me0)₂ can also be effected simultaneously with process step A) (not shown here). The mixture is transferred to a beaker and stirred at 25° C. and at 150 rpm for 0.5 to 1 hour. This gelation step is optional and therefore indicated by dotted lines. The gelation can be recognized by formation of homogeneously distributed gas bubbles in the material and a significant rise in viscosity.

In process step C), the purification step, the beaker is transferred to a drying cabinet, where water, hydrochloric acid and methanol are removed at 110° C. for one hour. Finally, the transparent composition precursor G in gel form can be isolated and cooled down to room temperature.

A composition precursor obtained as outlined above can be consolidated or cured by transferring it to a mold or cavity and curing it therein at 150 to 200° C. for 8 to 72 hours. The curing time is dependent on the proportions of the respective starting materials of the composition precursor and thickness of the sample to be cured. It is optionally possible, prior to commencement of curing, to add a small proportion of base or acid (only base shown here) to the composition precursor in order to reduce the curing time and temperature. This optional step is indicated by the dotted line. The cured composition CM is free of cracks and, according to the chosen viscosity of the composition precursor, flexible and elastic.

In process steps A) and B) as described in relation to FIG. 1, the trialkoxysilanes and dialkoxysilanes are hydrolyzed and form an oligomer and polymer chains, and partly crosslinked structures. Stepwise replacement of MeSi(OMe)₃ by Me₂Si(OMe)₂ leads to a more catenated and less crosslinked structure. This also reduces the viscosity of the composition precursor formed. The polydimethylsiloxane added in process step B) leads to additional opening-up of the network. If the temperature is increased during these steps, there is simultaneously an increase in viscosity, which simplifies the production process. A heat treatment of the composition precursors at temperatures exceeding 150° C. starts a further network-forming process. The composition precursors in gel form then form a firm but elastic polymer, the composition CM. This curing process does not require any catalysts or other components in order to cure the composition precursor. However, it is possible to catalyze the process by addition of small amounts of base or acid to the composition precursor. The consolidation time or curing time and temperature can be reduced by the pH dependence of the condensation reaction.

For example, the composition precursors G, for curing tests, can be introduced into PTFE molds of size 30×10×1 mm and, for transmission measurements, films of size 13×0.12 mm can be produced on glass plates. For this purpose, examples 1 and 2 that are specified in detail hereinafter were heated to 110° C. for better ease of handling. The film can be produced using the model 360 quadruple film applicator (Erichsen GmbH & Co. KG). The thickness of the films can be measured with a FMD12TB precision dial gauge (Kafer Messuhrenfabrik GmbH & Co. KG) with an accuracy of 1 μm. The samples prepared in this way can be cured, for example, at 200° C. for 72 hours in a drying cabinet. The transparent compositions CM are then cooled to room temperature and isolated.

Table 1 shows the exact proportions of the starting materials of the composition precursors according to examples 1 to 8:

TABLE 1

| | [symbol] | [symbol] | [symbol] | [symbol] | [symbol] | [symbol] | [symbol] | [symbol] |
|---|---|---|---|---|---|---|---|---|
| Sample | mmol | mmol | mmol | mmol | % | % | % | % |
| 1 | 25.23 | [symbol] | 2.62 | 0.36 | [symbol] | 94.17 | 9.14 | 0.68 |
| 2 | 25.27 | 20.07 | 5.12 | 0.36 | [symbol] | 89.24 | 10.08 | 0.68 |
| 3 | 25.23 | 15.01 | 10.20 | 0.35 | [symbol] | 79.22 | 20.09 | 0.68 |
| 4 | 25.21 | 12.83 | 12.72 | 0.36 | [symbol] | 74.43 | 24.89 | 0.68 |
| 5 | [symbol] | 9.98 | 15.23 | 0.36 | [symbol] | 69.23 | 30.09 | 0.68 |
| 6 | [symbol] | 8.71 | 16.57 | 0.37 | [symbol] | 66.72 | 32.59 | 0.68 |
| 7 | [symbol] | 7.49 | 17.75 | 0.35 | [symbol] | 64.38 | 34.93 | 0.68 |
| 8 | 25.21 | 4.93 | 20.36 | 0.35 | [symbol] | 59.28 | 40.03 | 0.68 |

[symbol]

indicates data missing or illegible when filed

Eight composition precursors (identified in table 1 as samples 1 to 8) were produced. Table 1 states the molar amounts n of the respective starting materials, and the proportions of the total trialkoxysilanes TAS, the dialkoxysilanes DAS and the polydimethylsiloxane PDMS in mol %. Additionally stated is the proportion of phenyl groups Ph [calc.]/Ph [¹H NMR], which should be considered in relation to the total number of alkyl and aryl groups. The calculated proportion of the amounts weighed out is divided here by the calculated proportion from the integration of the NMR spectra.

While the proportion of PhSi(OMe)₃ and PDMSi₁₁ (MeO)₂ was kept constant, the proportion of MeSi(OMe)₃ is replaced stepwise by Me₂Si(OMe)₂ in examples 1 to 8. This replacement of a methyltrialkoxysilane by a dimethylalkoxysilane leads to an opened-up and less crosslinked structure of the resulting composition precursor and hence also of the cured composition (CM). This results in a distinct reduction in viscosity of the composition precursors or hardness of the compositions. At the same time, there is an increase in the refractive index as a result of the greater ratio of phenyl to methyl groups.

Reference is also made to examples 1 to 8 hereinafter. When what are meant are the compositions produced from the respective composition precursors, the numbering 1 to 8 is retained and the addition CM is added.

FIG. 2 shows the molar amounts n in mmol of the starting materials used in examples 1 to 8 (x axis). It is again clearly apparent here that the proportion of PhSi(OMe)₃ and PDMSi₁₁(MeO)₂ in all examples was kept constant (square and downward-pointing triangle), whereas the proportions of MeSi(OMe)₃ (circle) and Me₂Si(OMe)₂ (upward-pointing triangle) were altered. In particular, the replacement of MeSi(OMe)₃ by Me₂Si(OMe)₂ is apparent.

The absolute values of the viscosities were measured with an MCR-301 rheometer having a CTD-450 convection heating system (Anton Paar GmbH, Austria) in oscillation with a plate-plate geometry (25 mm PP25 measurement plate), an amplitude of 5%, a frequency of 1 Hz and a normal force of 0.

FIG. 3 shows the averaged absolute values of the viscosity of samples 1 to 8 that were measured isothermally at 23° C. and at 110° C., in each case for 10 minutes. The absolute values of the viscosity at room temperature (|η*|@23° C. in mPas) and at 110° C. (|η*|@110° C. in mPas) can be determined directly after the synthesis of the composition precursors. It falls from example 1 to 8, i.e. with increase in the replacement of the MeSi(OMe)₃ content by Me₂Si(OMe)₂, as shown in FIG. 3. The viscosity of examples 1 and 2 is too high to be measured at room temperature. When the samples are heated to 110° C., the absolute viscosity value decreases significantly. All examples can be processed easily at 110° C. Samples 3 to 8, on account of their viscosity, can also be processed at room temperature, which makes the materials suitable, for example, as curable encapsulation material for optoelectronic components.

If the composition precursors are stored and hence subjected to an aging process, their viscosity can rise with the storage time at room temperature. If, for example, samples of example 4 are examined after storage for 60 days, it can be shown that the viscosity rises from 50 Pas to 420 Pas. This aging is caused by the still-flexible network of the composition precursor that enables further condensation reactions of the Si—OMe and Si—OH groups. The aging can be prevented or at least reduced when the samples are stored at lower temperature. However, the aged composition precursors can still be processed since they become softer at temperatures above 23° C.

When the composition precursors are used in encapsulations of optoelectronic components, it is important that they have a defined and preferably high refractive index. High refractive indices in composition precursors (and hence also in the compositions cured therefrom) can be promoted by the presence of mono- or polycyclic aromatic side groups. In samples 3 to 8, there is a change in the proportion of phenyl groups from 37% to 32%, as shown in FIG. 4 (left-hand y axis). At the same time, there is a change in the refractive index n_{D}²⁰ from 1.505 to 1.494 (right-hand y axis). The refractive index can be measured, for example, with an AR4 Abbé refractometer having a PT31 Peltier Thermostat (A. Krüss Optronic GmbH) at 20° C. with LED irradiation at 590 nm. The stepwise replacement of MeSi(OMe)₃ by Me₂Si(OMe)₂ results in a decrease in the proportion of phenyl groups in the samples, which means that the refractive index also falls. This shows that the drop in the refractive index correlates directly with the proportion of phenyl groups in the samples. The refractive index of samples 1 and 2 was not determinable on account of their very high viscosity at 20° C.

The values for the refractive indices between 1.505 and 1.494 of the composition precursors are high enough for use in optoelectronic components.

The replacement of MeSi(OMe)₃ by Me₂Si(OMe)₂, i.e. the proportion of phenyl groups in the composition precursors, can also adjust the hardness of the corresponding compositions, which may be subject to different demands according to the application. The hardness of the consolidated compositions can be measured at room temperature with a Shore A durometer. For this purpose, individual sample plaques can be placed one on top of another in order to attain the minimum thickness required for the purpose. FIG. 5 shows the hardness H in Shore A for examples 1 CM to 6 CM, which decreases with increasing proportion of Me₂Si(OMe)₂ and with increasing temperature. Samples 7 CM and 8 CM were too soft for a determination of hardness. A higher proportion of Me₂Si(OMe)₂ leads to longer and less crosslinked polymer chains. This opening-up of a previously close-mesh structure leads to the decrease in the hardness of the compositions.

The decreasing hardness among samples 3, 5 and 7 is also shown in FIG. 6, which shows images in which a 1.9 g magnet was placed onto each of the sample plaques. This does not lead to any bending in the case of the plaque made of a composition according to example 3 CM, but leads to significant bending in the case of the example 7 CM.

For applications in optoelectronic components, a high transparency of the encapsulation material is required. In white LEDs, for example, the entire visible spectrum of light is emitted. For a comparable transmission measurement, all samples of the composition precursors are processed to give a polymer film which is applied to glass plates by means of a film applicator (13×0.12 mm). As a result, all samples are homogeneous, with no inclusions or bubbles, and have a uniform thickness. These samples are cured in a drying cabinet at 200° C. for 72 hours. The consolidation process results in shrinkage of the samples. The actual film thickness was determined at three different sites for each sample, before the sample was analyzed by means of UV/VIS (Lambda 750 from Perkin Elmer Inc., USA, with a 100 mm integration range from 700 to 350 nm with a 2 nm increment and integration time 0.2 s). The film thickness for sample 1 CM is 81±1 μm, for sample 2 CM 61±2 μm, for sample 3 CM 51±5 μm, for sample 4 CM 95±8 μm, for sample 5 CM 63±2 μm, for sample 6 CM 48±2 μm, for sample 7 CM 42±2 μm, and for sample 8 CM 35±5 μm. All samples show transmittance values of more than 0.99 between 350 and 730 nm directly after the curing process. The shrinkage of the samples does not appear to be systematic. The high transparency is optimal for use in optical applications of any kind, especially in optoelectronic components.

Encapsulation materials for optoelectronic components must be castable, curable and impervious. If a composition precursor as encapsulation material is disposed in a component and then cured to form a composition, it must be free of cracks and bubbles and have a certain elasticity. In order to demonstrate the usability of the composition precursors in optoelectronic components, samples 4 and 6 were cast on a polyphthalamide LED leadframe (1.4×0.7×0.4 mm), and the leadframes were heat-treated at 160° C. for 20 hours to cure the composition precursors.

FIGS. 7a to f show images of the empty leadframe (FIGS. 7a and b), of the leadframe with a composition precursor from example 4 and of a composition 4 CM (FIGS. 7c and d), and a leadframe with a composition precursor from example 6 and a composition 6 CM (FIGS. 7e and f). The image in FIG. 7a is focused on the metallic substrate, and in FIG. 7b on the upper edge of the leadframe. In FIG. 7c, the color impression is generated by the metallic baseplate; the same applies to FIG. 7d. The bubbles that are visible in FIG. 7e and were produced as a result of the application of the composition precursor disappear after the curing process, as can be seen in FIG. 7f. Both cast composition precursors 4 and 6 show very good processibility. After curing, no bubbles or cracks can be measured within the compositions 4 CM and 6 CM. Shrinkage of the materials can be recognized from the lateral edges of the leadframes as reference before and after curing. Overall, the composition precursors and hence also the compositions are of good suitability for encapsulation material for LED applications.

A further important property in various applications of composition precursors and compositions, including in LED applications, is a high thermal stability of the material. Under working conditions, the local temperature in an LED can rise to above 150° C. Therefore, the cured compositions were heated up to 800° C. at a heating rate of 10 K/min and under

N₂/0₂ with a gas flow rate of 20 ml/min (using a TG209 Fl Libra thermo-microbalance from Netzsch-Geratebau GmbH), in order to measure their breakdown characteristics, as can be seen in FIG. 8. The temperature at which 95% of the mass of the sample remains after breakdown is defined as the T₉₅ value. The higher the T₉₅ value, the more thermally stable the composition. FIG. 8a shows the thermogravimetric loss of mass of examples 1 CM to 8 CM. The mass M in % is plotted against the temperature T in ° C. All samples show high thermal stability up to 400° C. FIG. 8b shows the T₉₅ values obtained for compositions 1 CM to 8 CM. This is above 360° C. for all samples, which makes them suitable for applications in which working temperatures are high. No breakdown of the samples is measured below 200° C. This too indicates very high thermal stability of the samples.

As already mentioned, the curing process for production of the composition can be catalyzed by the addition of small amounts of a base or acid to the composition precursor. The base can be added to the composition precursors, for example, directly prior to the heat treatment. For example, it is possible to use KOH and DABCO as bases. In order to show the change in viscosity, in a composition precursor of example 4 that was aged for 60 days, viscosity was measured isothermally at 110° C. after addition of different amounts of KOH. In sample 4-MO no KOH was added, in sample 4-M1 5.5 mmolg⁻¹ was added, and 13.9 mmolg⁻¹ was added to sample 4-M2. For this purpose, potassium hydroxide (0.093 g, 1.65 mmol) was dissolved in methanol (14.949 ml, 0.369 mol, 0.11 mol/1). The amounts of 0.0, 1.0 and 2.5 μl of this solution were added to the samples from example 4 (0.2 g) and mixed.

All three examples show a drop in viscosity |η*| with an initial rise in the temperature T. Samples 4-M1 and 4-M2 show a significant rise in viscosity at 110° C., whereas the viscosity of 4-MO remains virtually constant. This means that the rise in viscosity is directly correlated with the proportion of KOH that was added to the samples. These correlations are shown in FIG. 9, in which the time t in min is given on the X axis, the viscosity |η*| in mPas on the left-hand Y axis, and the temperature T in ° C. on the right-hand Y axis. Viscosity was measured with an oscillation rheometer at 5 K/min and an amplitude of 5% at a frequency of 1 Hz and a normal force of 0 N, beginning at 110° C. It is thus possible to show that the curing time and temperature can be adjusted for each requirement by appropriately selecting the amount of base added. The curing temperature has to be optimized for each composition in order to avoid formation of bubbles on account of methanol formation, for example. When the composition cures too quickly, bubbles will remain therein. Pretreatment under reduced pressure prior to the casting of the composition precursor can remove residues of solvent. If a relatively weak base is used without solvent, for example DABCO (pK_{b}=5.2), it is likewise possible to prevent or reduce the formation of bubbles.

All samples show the expected vibration bands in measurements by means of FTIR spectroscopy (measured in total reflection mode with a Vertex 70 spectrometer from Bruker Corp., USA, from 4500 to 400 cm⁻¹ with a 4 nm increment and 10 averaged scans). The FTIR spectra of examples 1 to 8 are shown in FIG. 10a, where the relative absorption Aᵣₑₗ is given as a function of energy E in cm⁻¹. It is thus also possible to show the stepwise replacement of the methyltrimethoxysilanes by dimethyldimethoxysilanes. The replacement results in a decrease in the intensity of the band at 1269 cm⁻¹, while there is a rise in the intensity in the band at 1259 cm⁻¹. FIG. 10b shows an enlarged detail of the FTIR spectrum of examples 1 to 8, which shows the decrease in the vibration band at 1269 cm⁻¹ that is caused by the decreasing proportion of MeSi(OMe)₃ in the examples. Also shown is the rise in the vibration band at 1259 cm⁻¹ which is caused by an increasing content of Me₂Si(OMe)₂.

The condensation behavior of various monomer units that are used in the synthesis of the composition precursor can be monitored by means of two-dimensional ²⁹Si-¹H nuclear resonance spectroscopy (2D-NMR). The results of a heteronuclear multiple bond correlation (HMBC) experiment on composition precursors 1, 2, 3 and 8 are shown in table 2 below. For performance of the experiment, small amounts of the samples of the respective reaction mixture were taken after 3 hours of hydrolysis (before the addition of the PdMSi₁₁ (MeO)₂) and on conclusion of synthesis of the respective composition precursors. What are reported in each case are ranges for the peaks, since there is a high concentration of different types of molecules (hydrolyzed and non-hydrolyzed molecules, monomers, oligomers, polymers, rings etc.) that make the ²⁹Si chemical shifts very broad and therefore make resolution difficult.

TABLE 2

| [symbol] | [symbol] | [symbol] | F | 1 | 2 | 3 | 8 |
|---|---|---|---|---|---|---|---|
| −78...−80 | 7.82...7.4 | — | T³ | + | + | + | + |
| −71...−74 | 7.82...7.4 | 3.65...3.28 | T² | + | + | + | + |
| −66...−69 | 7.82...7.4 | 3.65...3.28 | T² | + | + | + | + |
| −59...−64 | 7.82...7.4 | 3.65...3.28 | T¹ | + | + | + | + |
| −62...−68 | 0.36...−0.26 | — | T³ | + | + | + | + |
| −56...−60 | 0.36...−0.26 | 3.65...3.28 | T² | + | + | + | + |
| −52...−56 | 0.36...−0.26 | 3.65...3.28 | T² | + | + | + | + |
| −44...−50 | 0.36...−0.26 | 3.65...3.28 | T¹ | + | + | + | + |
| −18...−22 | 0.36...−0.26 | — | D² | + | + | + | + |
| −15...−18 | 0.36...−0.26 | — | D² | + | + | + | + |
| −9.5...−12 | 0.36...−0.26 | — | D₁¹ | + | + | − | − |
| −9.5...−12 | 0.36...−0.26 | 3.65...3.28 | D₀¹ | − | − | + | + |
| 2...−5 | 0.36...−0.26 | 3.65...3.28 | D₀ | − | − | + | + |

[symbol]

indicates data missing or illegible when filed

The corresponding spectra together with the ¹H NMR spectra of the other examples of the composition precursors are shown in FIGS. 15 to 26.

The figures show:

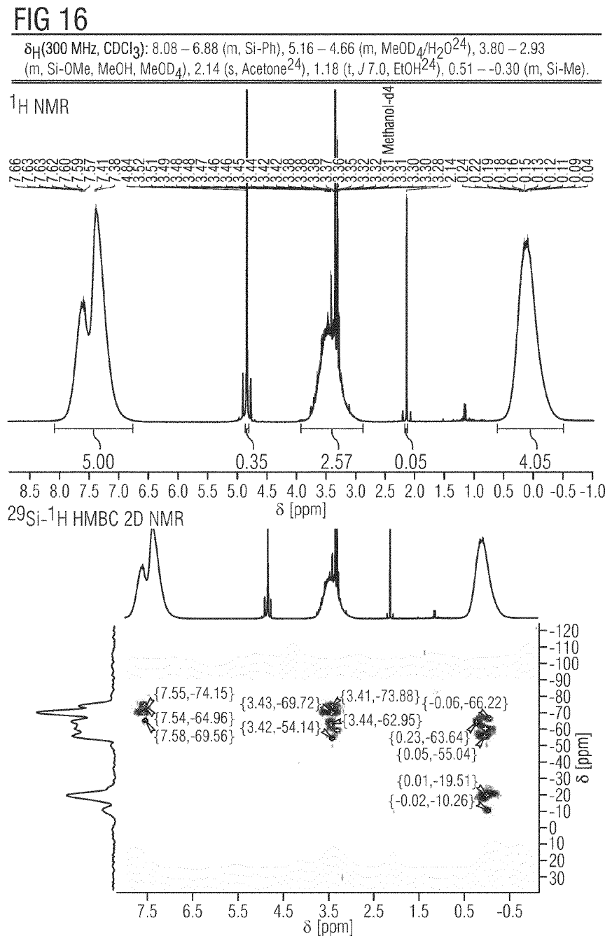

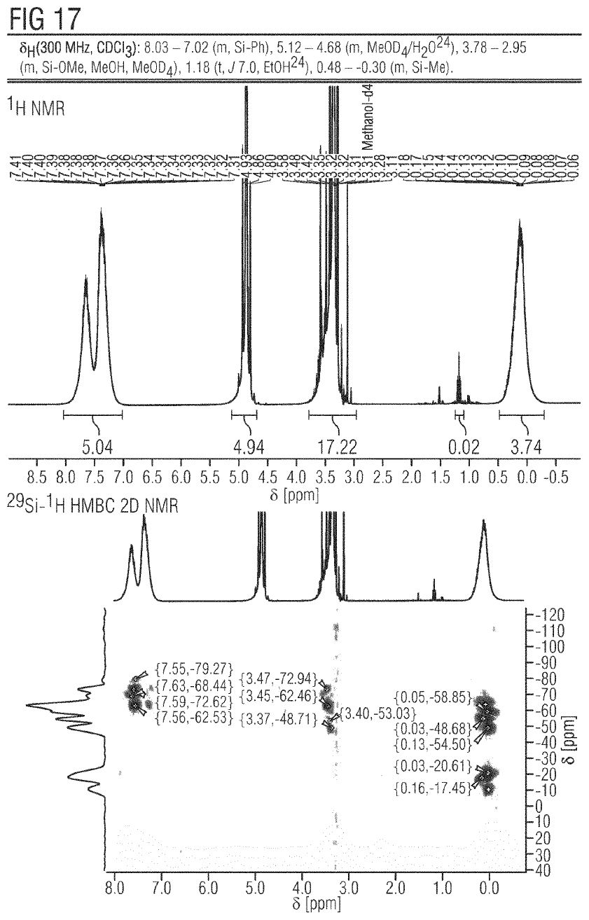

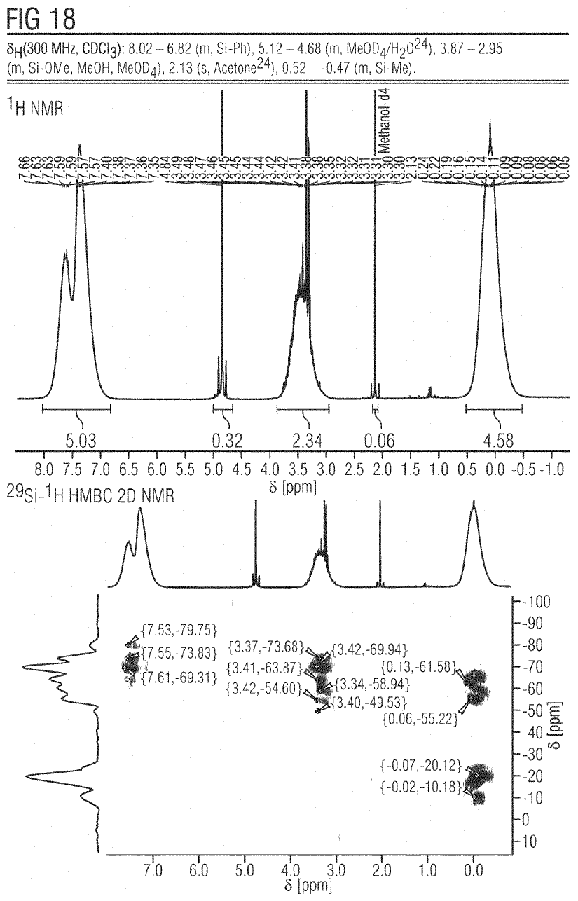

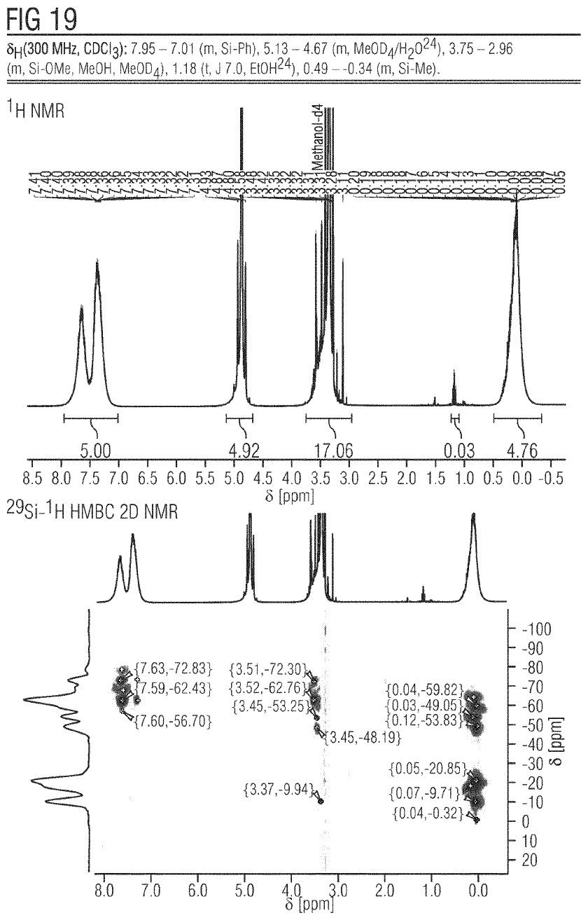

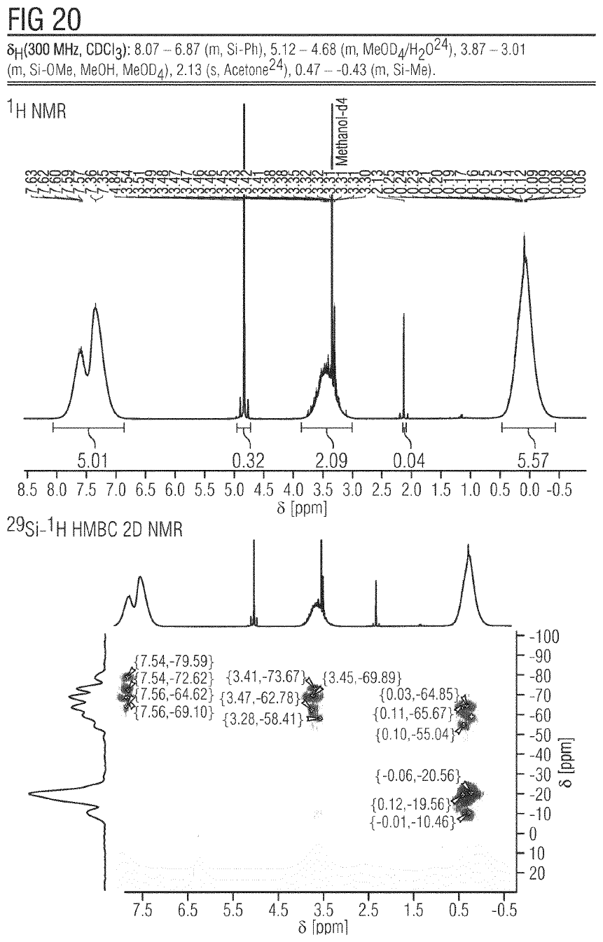

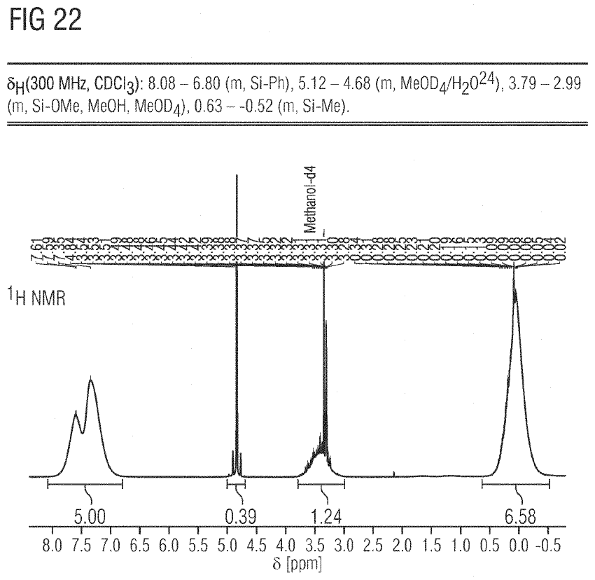

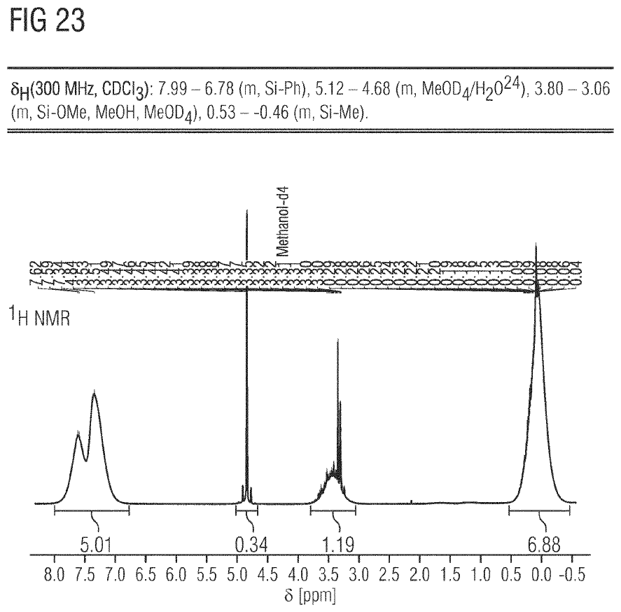

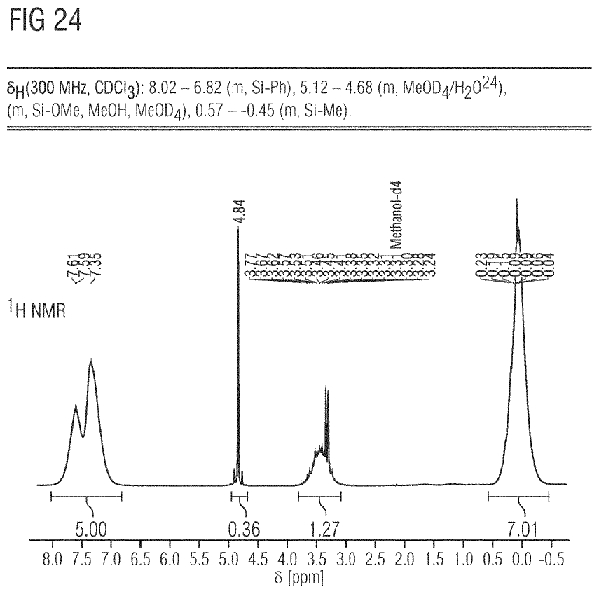

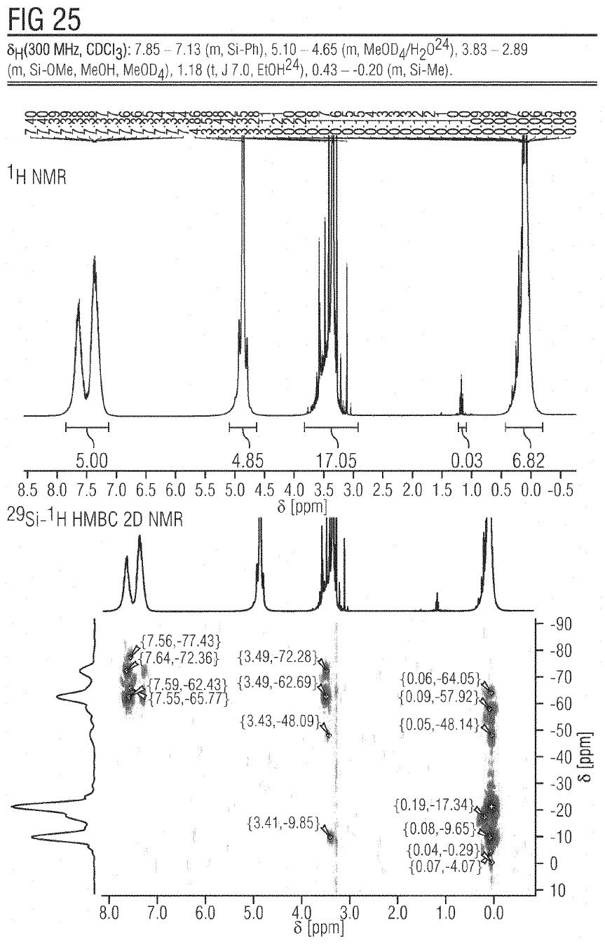

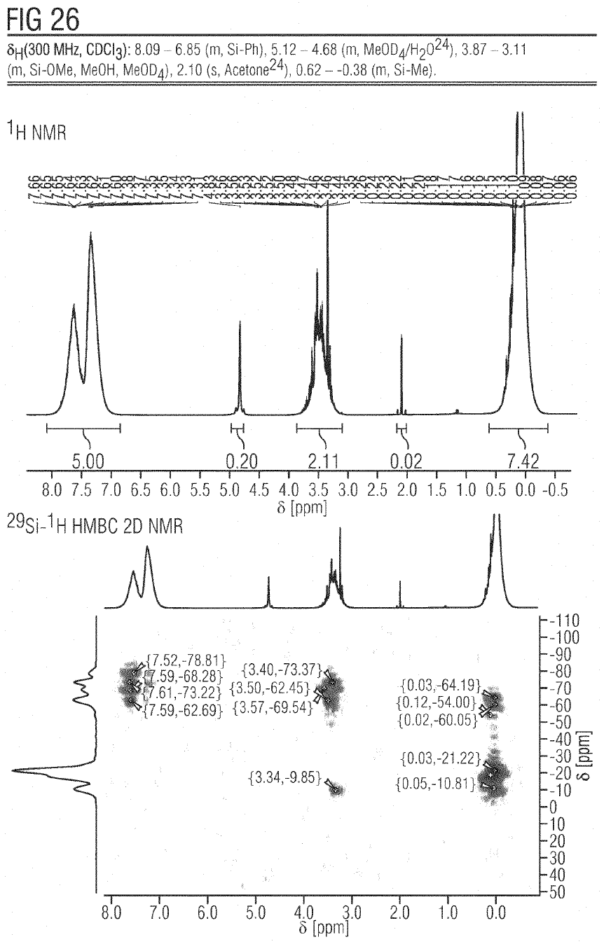

FIG. 15: sample 1 after 3 h, FIG. 16: sample 1 after synthesis, FIG. 17: sample 2 after 3 h, FIG. 18: sample 2 after synthesis, FIG. 19: sample 3 after 3 h, FIG. 20: sample 3 after synthesis, FIG. 21: ¹H NMR spectrum of sample 4, FIG. 22: ¹H NMR spectrum of sample 5, FIG. 23: ¹H NMR spectrum of sample 6, FIG. 24: ¹H NMR spectrum of sample 7, FIG. 25: sample 8 after 3 h, FIG. 26: sample 8 after synthesis.

The spectra of samples 1, 2, 3 and 8 show the possible chemical shifts of the trifunctional T unit except for T⁰ (see also table 2, in which the functional groups F are specified). This shows that the phenyltrimethoxysilane monomers and methyltrimethoxysilane monomers have reacted at least once with a second molecule or part of a linear or crosslinked structure. In addition, it appears that every T signal except for T³ is coupled to the chemical shift of the methoxy groups. It can be concluded from this that significantly few trifunctional molecules have been hydrolyzed before they have reacted with other molecules.

The chemical shifts that are caused by difunctional D units of Me₂Si(OMe)₂ groups show different behavior. In samples 1 and 2, it is not possible to detect any unreacted D⁰ signals. All monomers reacted at least once with a second molecule or part of a linear or crosslinked structure, as can be observed from the D¹ and D² signals observed. The D¹signals can be divided into D¹₀ and D¹₂ signals. The numbers indicated show the proportion of hydroxyl groups bonded to a molecule. A D¹₀ signal is generated by a monomer having no hydroxyl group; a D¹₂ signal is generated by a monomer having one hydroxyl group. The additional D¹₂ signal can be separated by the chemical shift and is measurable since there is no coupling with the methoxy groups. In the spectra of samples 3 and 8, it is also possible to observe D¹ signals of the end groups and D² signals of linear or crosslinked units. D⁰ signals can be measured on unreacted monomers. The reaction does not yet appear to have ended after stirring for three hours. Thus, TAS monomers are reacting with one another and with DAS monomers, forming linear and crosslinked structures. When the DAS concentration is increased, the number of unreacted DAS monomers increases, whereas the number of unreacted TAS monomers in each sample is 0. It can be concluded from this that the condensation reaction between TAS and DAS monomers is preferred compared to a reaction between two DAS molecules. After further synthesis steps, no D⁰ signals are measurable any longer. The monomers have reacted with the structures formed beforehand.

FIG. 27 shows the schematic side view of an optoelectronic component according to a working example. The component, for example an LED, comprises a substrate 10 with a semiconductor layer sequence 20 disposed thereon. The semiconductor layer sequence 20 is set up to emit primary radiation, for example short-wave light having a wavelength maximum of about 450 nm.

A conversion layer 30 is disposed in the beam path of the primary radiation. This encases the semiconductor layer sequence 20 completely, i.e. in a cohesive and form-fitting manner, and is thus introduced as an encapsulant in a recess of the housing 40. The conversion layer 20 thus serves firstly as encapsulation for the semiconductor layer sequence 20, and secondly for conversion of the primary radiation to a secondary radiation. The conversion layer comprises a dye included in a matrix formed from a composition.

Alternatively, the conversion layer 30 may be disposed at a distance from the semiconductor layer sequence 20 (not shown here). In this case, an encapsulation formed from the composition may be disposed between the semiconductor layer sequence 20 and the conversion layer 30.

The invention is not limited to the working examples by the description on the basis thereof. Instead, the invention encompasses every new feature and every combination of features, which especially includes every combination of features in the claims, even if this feature or the combination itself is not explicitly specified in the claims or working examples.

### LIST OF REFERENCE NUMERALS

10 substrate

20 semiconductor layer sequence

30 conversion layer

40 housing

A process step A

B process step B

C process step C

n molar amount

|η*| absolute viscosity

n_{D}²⁰ refractive index

H hardness

M mass

T temperature

T₉₅ value

t time

Aᵣₑₗ relative absorption

E energy

G composition precursor

CM composition

1. A composition precursor having a three-dimensional network of partly mutually crosslinked monomer units and an alkoxy-terminated oligo- or polysiloxane, wherein the monomer units comprise at least one trialkoxysilane and at least one dialkoxysilane.

2. The composition precursor as claimed in claim 1, having the general structural formula 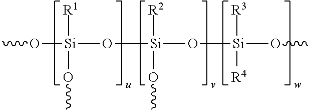
where R¹, R², R³ and R⁴ are independently selected from aryl, alkyl, alkenyl, allyl, substituted aryl, substituted alkenyl, substituted alkyl and vinyl, preferably from phenyl and methyl, where u+v+w is the number of silicon atoms used and u, v and w are independently selected from the range of 1 to 20 000.

3. The composition precursor as claimed in claim 1, wherein the proportion of alkoxy-terminated oligo- or polysiloxane is selected from a range from >0% to 10% of the sum total of the molar amounts of trialkoxysilane and dialkoxysilane.

4. The composition precursor as claimed in claim 1, having a viscosity at 23° C. within a range from 1 000 000 mPas to 100 mPas and/or having a viscosity at 110° C. within a range from 10 000 mPas to 50 mPas.

5. The composition precursor as claimed in claim Jany of the preceding claims, which is thermally or photochemically curable.

6. A composition comprising a thermally or photochemically cured position precursor as claimed in claim 1.

7. The composition as claimed in claim 1, having a Shore A hardness of 40 to <99.

8. The composition as claimed in claim 6, which is free of a precious metal catalyst.

9. A process for producing a composition precursor, comprising the steps of
A) condensing at least one trialkoxysilane and at least one dialkoxysilane,
B) condensing the trialkoxysilane and the dialkoxysilane with an alkoxy-terminated oligo- or polysiloxane,
C) purifying the condensed trialkoxysilane, dialkoxysilane and alkoxy-terminated oligo- or polysiloxane, wherein process step B) is performed after process step A) or simultaneously with process step A).

10. The process as claimed in claim 9, wherein process steps A) and B) are performed at a temperature selected from the range of 20° C. to 60° C., and/or process step C) is performed at a temperature selected from the range of 70° C. to 150° C.

11. The process as claimed in claim 9, wherein process step A) is performed with addition of an acid or base.

12. The process as claimed in claim 9, wherein process step C) is preceded by stirring of the condensed trialkoxysilane, dialkoxysilane and alkoxy-terminated oligo- or polysiloxane at room temperature.

13. A process for producing a composition, in which a composition precursor produced as claimed in claim 9, is thermally or photochemically cured.

14. The process as claimed in claim 13, wherein the thermal curing is performed at a temperature from the range of 150° C. to 250° C. and/or for a duration from the range of 8 h to 72 h.

15. The process as claimed in claim 13, wherein a base or acid as catalyst is added to the composition precursor.

16. The use of a composition as claimed in claim 6, encapsulation material for optoelectronic components, as matrix material for conversion layers, as lens material, as anticorrosion material, as component in composite materials, in lithography processes in printing technology.

17. A component including at least one assembly comprising a composition as claimed in claim 6.

18. The component as claimed in claim 17, which is an optoelectronic component and comprises an encapsulation including the composition and/or a conversion layer including the composition.

19. The component as claimed in claim 18, wherein the composition in the conversion layer is a matrix material for a wavelength-converting dye.
